(19) United States
(12) Patent Application Publication
(10) Pub. No.: US 2011/0147602 A1
(43) Pub. Date: Jun. 23, 2011

(54) RADIOGRAPHIC IMAGING APPARATUS, RADIOGRAPHIC IMAGING SYSTEM, AND METHOD OF PRODUCING RADIOGRAPHIC IMAGING APPARATUS

(75) Inventors: Yohei Ishida, Honjo-shi (JP); Satoshi Okada, Tokyo (JP); Kazumi Nagano, Fujisawa-shi (JP); Masato Inoue, Kumagaya-shi (JP); Shinichi Takeda, Honjo-shi (JP); Keiichi Nomura, Honjo-shi (JP); Satoru Sawada, Kodama-gun (JP)

(73) Assignee: CANON KABUSHIKI KAISHA, Tokyo (JP)

(21) Appl. No.: 12/969,199

(22) Filed: Dec. 15, 2010

(30) Foreign Application Priority Data
Dec. 18, 2009 (JP) 2009-288460

(51) Int. Cl. G01T 1/20; H01L 31/115; H01L 31/18

(52) U.S. Cl. 250/370.11; 257/428; 438/57; 257/E31.06

(57) ABSTRACT

A radiographic imaging apparatus includes a sensor panel having an effective pixel region and a peripheral region surrounding the effective pixel region; a scintillator layer disposed on the effective pixel region and the peripheral region of the sensor panel; and a scintillator protecting layer disposed on the scintillator layer. The scintillator layer includes a plurality of columnar crystals disposed on the effective pixel region, a plurality of columnar crystals disposed on the peripheral region, and a resin disposed between the plurality of the columnar crystals on the peripheral region and surrounding the plurality of the columnar crystals on the effective pixel region. The plurality of the columnar crystals on the effective pixel region is enclosed by the sensor panel, the scintillator layer, and the resin.

### BACKGROUND OF THE INVENTION

1. Field of the Invention

The present invention relates to a radiographic imaging apparatus, a radiographic imaging system, and a method of producing a radiographic imaging apparatus.

2. Description of the Related Art

In some known radiographic imaging apparatuses, an organic film and an aluminum film covering the upper portion and side surface of a scintillator layer and the outer-area of a substrate are formed by vapor deposition (see U.S. Pat. No. 6,262,422). Another known radiographic imaging apparatus includes a frame ring disposed over an optical sensor array at the periphery of an effective portion and surrounding the outer side wall of a scintillator, and a frame ring cover airtightly joined to the frame ring and extending over the scintillator (see U.S. Pat. No. 5,132,539). Furthermore, another known radiographic imaging apparatus includes a phosphor film where columnar crystals are in contact with adjacent columnar crystals through the interfaces without gaps in the film surface direction, and photoelectric conversion elements (see Japanese Patent Laid-Open No. 2008-032407).

In the scintillator layer formed on the substrate by vapor deposition, as shown in the scintillator layer of U.S. Pat. No. 6,262,422, the thickness of the periphery is smaller than that of the central portion. Since Cesium Iodide (CsI), which is widely used for forming scintillator layers, is a material that rapidly absorbs moisture from air, and deliquesces (breaks down due to moisture), the scintillator layer is protected by an organic or inorganic protective layer covering a region larger than the surface area of the scintillator layer.

The apparatus of U.S. Pat. No. 5,132,539 is large in size because of the frame ring disposed with a space from the outer side wall of the scintillator.

In the apparatus of Japanese Patent Laid-Open No. 2008-032407, since the adjacent columnar crystals of the phosphor film are in contact with adjacent columnar crystals without gaps to form an assembly, light generated in a columnar crystal spreads to the adjacent columnar crystals, resulting in a reduction in sharpness.

The radiographic imaging apparatus has a region (effective pixel region) being capable of photographing and a region (peripheral region) not being capable of photographing on the outer side of the effective region, and the portion where the thickness of the scintillator layer is reduced is usually formed outside the effective pixel region.

Such a structure causes a reduction in the degree of freedom of photographing.

### SUMMARY OF THE INVENTION

The present invention provides a radiographic imaging apparatus having an increased degree of freedom of photographing.

An aspect of the present invention relates to a radiographic imaging apparatus including a sensor panel having an effective pixel region and a peripheral region surrounding the effective pixel region; a scintillator layer disposed on the effective pixel region and the peripheral region of the sensor panel; and a scintillator protecting layer disposed on the scintillator layer. The scintillator layer has a plurality of columnar crystals disposed on the effective pixel region, a plurality of columnar crystals disposed on the peripheral region, and a resin disposed between the plurality of the columnar crystals on the peripheral region and surrounding the plurality of the columnar crystals on the effective pixel region. The plurality of the columnar crystals on the effective pixel region is enclosed by the sensor panel, the scintillator layer, and the resin.

Another aspect of the present invention relates to a method of producing a radiographic imaging apparatus including preparing a sensor panel having an effective pixel region where a plurality of pixels having photoelectric conversion elements are arranged and a peripheral region surrounding the effective pixel region; forming a scintillator layer having a plurality of columnar crystals on the effective pixel region and on the peripheral region of the sensor panel; applying a resin among the columnar crystals on the peripheral region of the sensor panel; and forming a scintillator protecting layer covering the effective pixel region and the peripheral region.

In the radiographic imaging apparatus of the present invention, the peripheral region can be narrowed, resulting in an increase of the degree of freedom of photographing.

Further features of the present invention will become apparent from the following description of exemplary embodiments with reference to the attached drawings.

### BRIEF DESCRIPTION OF THE DRAWINGS

FIG. 1A is a plan view illustrating a radiographic imaging apparatus according to an embodiment of the present invention.

FIG. 1B is a cross-sectional view illustrating the radiographic imaging apparatus according to the embodiment of the present invention.

FIG. 2A is a partial cross-sectional view illustrating an example of the radiographic imaging apparatus shown in FIG. 1B.

FIG. 2B is a partial cross-sectional view illustrating an example of the radiographic imaging apparatus shown in FIG. 1B.

FIG. 3A is a partial cross-sectional view illustrating an example of the radiographic imaging apparatus shown in FIG. 1B.

FIG. 3B is a partial cross-sectional view illustrating an example of the radiographic imaging apparatus shown in FIG. 1B.

FIGS. 4A to 4D are partial cross-sectional views illustrating an example of a method of producing a radiographic imaging apparatus according to the present invention.

FIGS. 5A to 5E are partial cross-sectional views illustrating an example of another method of producing a radiographic imaging apparatus according to the present invention.

FIG. 6 is a plan view illustrating a radiographic imaging apparatus produced by the method of producing a radiographic imaging apparatus shown in FIGS. 5A to 5E.

FIG. 7A is a partial cross-sectional view illustrating an example of a radiographic imaging apparatus according to the present invention.

FIG. 7B is a partial cross-sectional view illustrating an example of a radiographic imaging apparatus according to the present invention.

FIG. 8 is a configuration diagram illustrating an example where an imaging apparatus according to the present invention is applied to a radiographic imaging system.

### DESCRIPTION OF THE EMBODIMENTS

The best modes for carrying out the present invention will be described in detail with reference to the accompanying drawings.

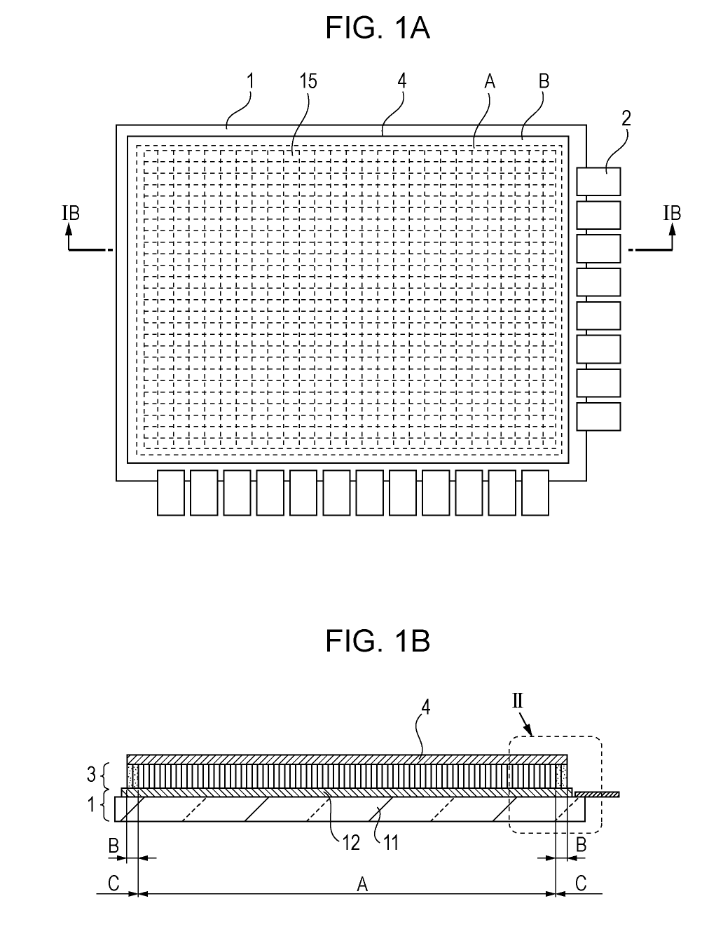

FIGS. 1A and 1B show a radiographic imaging apparatus according to an embodiment of the present invention. FIG. 1A is a plan view, and FIG. 1B a cross-sectional view taken along the line IB-IB in FIG. 1A.

As shown in FIGS. 1A and 1B, the radiographic imaging apparatus includes a sensor panel 1, peripheral circuits 2 arranged in the periphery of the sensor panel 1, a scintillator layer 3, and a scintillator protecting layer 4. The scintillator layer 3 is arranged between the sensor panel 1 and the scintillator protecting layer 4.

In FIG. 1A, the region A surrounded by a broken line is the effective pixel region, namely, a region capable of photographing, of the radiographic imaging apparatus. A plurality of pixels 15 are arranged in the region A. The region defined by the broken line and the outer edge of the scintillator protecting layer 4 is a sealing region B.

As shown in FIG. 1B, the sealing region B is formed around the periphery of the scintillator layer 3 disposed over an active matrix array, and serves as a sealing for protecting the scintillator layer 3 that easily deliquesces due to moisture from the outside. A peripheral region C of the active matrix is the outside of the region A and is a region not capable of photographing.

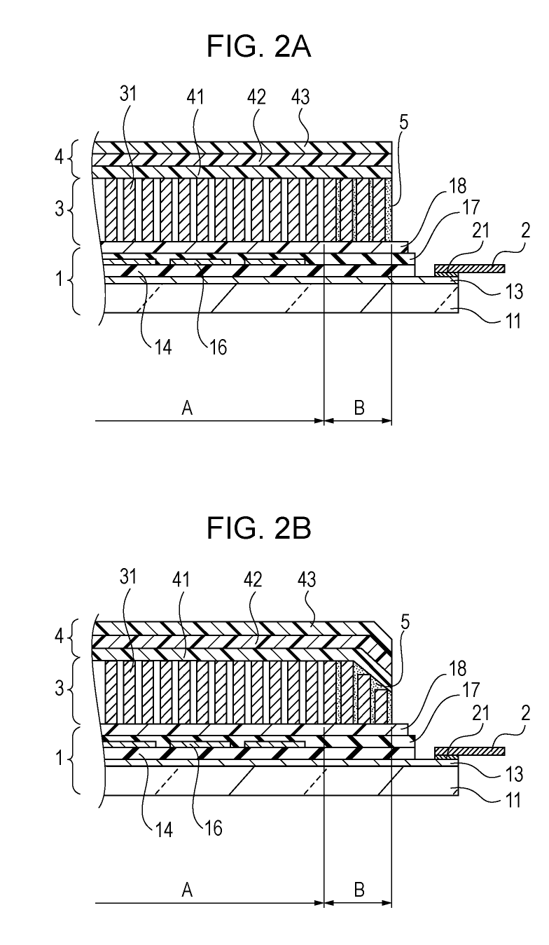

FIGS. 2A and 2B are enlarged partial cross-sectional views of the portion surrounded by a broken line II in FIG. 1B. FIG. 2A shows a structure where the scintillator layer 3 has a substantially uniform thickness, and FIG. 2B shows a structure where the peripheral region C of the scintillator layer 3 has a thickness smaller than that of the effective pixel region A. The sensor panel 1 has a substrate 11, wiring 13 arranged on the substrate 11 so as to correspond to the active matrix array 12, a first insulating layer 14, photoelectric conversion elements 16 included in the respective pixels, a second insulating layer 17, and a protective layer 18. The pixel includes a photoelectric conversion element 16 and a switching element (not shown). The switching element is connected to the wiring 13. A signal charge generated by photoelectric conversion of the photoelectric conversion element 16 is transferred to a peripheral circuit 2 through the switching element and the wiring 13. The wiring 13 and the peripheral circuit 2 are connected to each other by a connecting member 21. The scintillator layer 3 has a plurality of columnar crystals and is disposed on the protective layer 18. The sealing region B of the scintillator layer 3 is sealed by a sealing member 5. The scintillator layer 3 shown in FIG. 2A can be formed by, for example, forming columnar crystals in a region broader than the entire area of the effective pixel region A and the sealing region B by vapor deposition and then removing the columnar crystals formed on the outside than the sealing region B. The scintillator layer 3 shown in FIG. 2B can be formed by, for example, forming columnar crystals by vapor deposition under a state that the region on the outside of the sealing region B, that is, the peripheral region C, is masked. In the present invention, the periphery of the scintillator layer 3 on the outside of the effective pixel region A is used as the sealing portion, and, thereby, the area of the scintillator protecting layer 4 can be reduced in size to narrow the peripheral region C, which can achieve a reduction in size of the radiographic imaging apparatus. In the structure shown in FIG. 2B, since the periphery of the scintillator layer 3 has a portion having a thickness smaller than that of the scintillator layer 3 in the effective pixel region A, the side face area of the sealing portion being in contact with the outside is reduced, which improves moisture resistance. The scintillator layer 3 on the outside of the region A is used as the sealing portion, and, thereby, the region of the scintillator protecting layer 4 can be reduced in size to narrow the peripheral region C, which can achieve a reduction in size of the radiographic imaging apparatus.

The substrate 11 may be an insulating substrate such as glass or a resin.

The photoelectric conversion element 16 may be a MIS-, PIN-, or TFT-type photoelectric conversion element made of, for example, amorphous silicon. The switching element may be a TFT or a diode switch. The photoelectric conversion element 16 and the switching element may be stacked or arranged in flat.

The first insulating layer 14 may be an inorganic or organic insulating film or an insulating multilayer composed thereof. The inorganic insulating film is made of, for example, silicon nitride (SiNx, where x is a number greater then 0) and is usually used as a protective film for the switching elements. The organic insulating film is made of, for example, an acrylic resin, a polyimide resin, or a siloxane resin. When the photoelectric conversion element 16 and the switching element are stacked, the first insulating layer 14 is disposed between the photoelectric conversion element 16 and the switching element.

The second insulating layer 17 may be an inorganic or organic insulating film. The inorganic insulating film is made of, for example, SiNx. The organic insulating film is made of, for example, a polyphenylene sulfide resin, a fluorine resin, a polyether ether ketone resin, a liquid crystal polymer, a polyethylene naphthalate resin, a polysulfone resin, a polyethersulfone resin, or a polyacrylate resin. Alternatively, the organic insulating film may be made of a polyamide imide resin, a polyether imide resin, a polyimide resin, an epoxy resin, or a silicone resin.

The protective layer 18 is made of, for example, a polyamide imide resin, a polyether imide resin, a polyimide resin, an epoxy resin, or a silicone resin. Since the second insulating layer 17 and the protective layer 18 transmit light converted from radiation by the scintillator layer 3, they should be made of materials having high transmittance at the wavelength of light emitted by the scintillator layer 3.

The connecting member 21 may be, for example, a soldered or anisotropically-conductive film (ACF).

The peripheral circuits 2 may be, for example, a flexible wiring board mounted with electronic components such as IC.

The scintillator layer 3 converts radiation to light that can be detected by the photoelectric conversion element 16 and has a plurality of columnar crystals 31 formed on the effective pixel region and on the peripheral region of the sensor panel 1. In the scintillator layer 3 having the plurality of the columnar crystals 31, since the light generated in the columnar crystal 31 propagates inside the columnar crystal 31, light scattering is low, which gives satisfactory resolution. The scintillator layer 3 having the columnar crystals 31 can be made of an alkali halide-based material, such as CsI:Tl, CsI:Na, CsBr:Tl, NaI:Tl, LiI:Eu, or KI:Tl. For example, a scintillator layer 3 of CsI:Tl can be formed by simultaneously vapor-depositing CsI and TlI. Note that a portion where the thickness of the scintillator layer is small tends to be low in brightness.

The sealing member 5 can be made of a material having high moisture resistance and low moisture permeability. For example, a resin material such as an epoxy resin or an acrylic resin can be used, and a silicone, polyester, polyolefin, or polyamide resin can be also used.

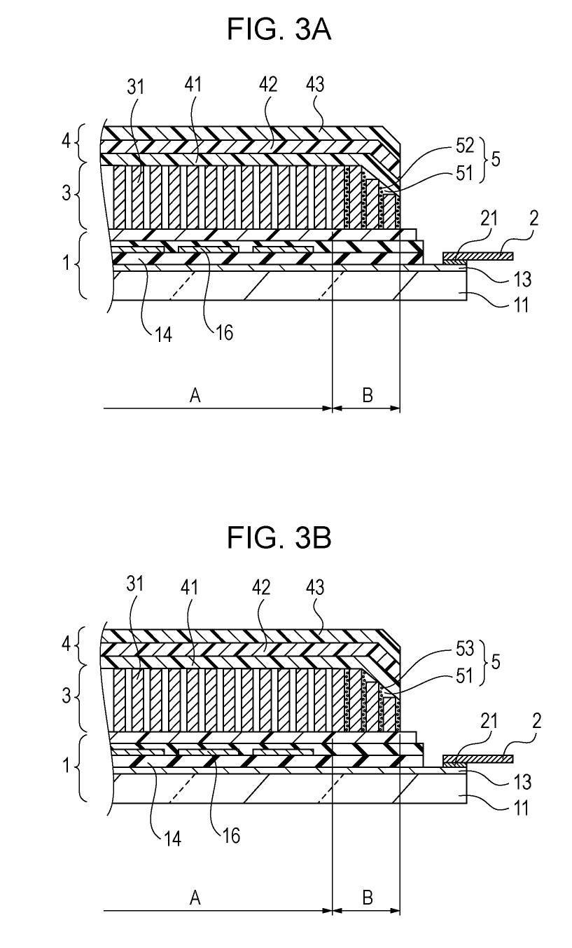

The sealing member 5 may be disposed on the periphery of the scintillator layer 3, in particular, on the outer edge of the scintillator layer 3 where the thickness of the scintillator layer 3 is 80% or less of the average thickness of the effective pixel region A. By reducing the thickness of the scintillator layer 3 in the periphery, the side face area of the sealing portion being in contact with the outside is reduced, which further improves moisture resistance. Furthermore, the portion of the scintillator layer where the brightness decreases can be used as the sealing. The sealing member 5 may be constituted of a resin 51 and a light-absorbing member 52 uniformly contained in the resin 51, as shown in FIG. 3A. That is, the sealing member 5 has a constitution where the resin 51 contains the light-absorbing member 52 therein. Examples of the light-absorbing member 52 include particles of inorganic pigments such as carbon black, ivory black, mars black, peach black, and lamp black; and particles of organic pigments such as aniline black. The light-absorbing member 52 contains at least one material selected from the above-mentioned materials. Alternatively, the sealing member 5 may be constituted of a resin 51 and a light-reflecting member 53 uniformly contained in the resin 51, as shown in FIG. 3B. That is, the sealing member 5 has a constitution where the resin 51 contains the light-reflecting member 53 therein. Examples of the light-reflecting member 53 include particles of titanium oxide and zinc oxide. The sealing member 5 thus-constituted of the resin and the light-absorbing member or the light-reflecting member can reduce the amount of outside light entering the effective pixel region A from the periphery of the scintillator layer 3. Therefore, the radiographic imaging apparatus can form an image with satisfactory quality.

The scintillator protecting layer 4 has a moisture-proof function of preventing infiltration of moisture from the outside into the scintillator layer 3 and a shock-absorbing function of preventing breakage of the scintillator layer 3 by shock from the outside. The scintillator protecting layer 4 covers a plurality of pixels and extends onto the sealing member 5. The scintillator protecting layer 4 may have a single-layer or multilayer structure. The scintillator protecting layer 4 having a single-layer structure is a reflective layer only. The scintillator protecting layer 4 having a double-layer structure is composed of, for example, a resin layer and a reflective layer from the scintillator layer 3 side, and the scintillator protecting layer 4 having a three-layer structure is composed of, for example, a first resin layer, a reflective layer, and a second resin layer from the scintillator layer 3 side. In the scintillator layer 3 having a columnar crystal structure, the resin layer 41 of the scintillator protecting layer 4 disposed on the scintillator layer 3 side can have a thickness of 20 to 200 μm. A resin layer 41 having a thickness of smaller than 20 μm cannot sufficiently cover the asperities on the surface of the scintillator layer 3. This may decrease the moisture-proof function. Conversely, a resin layer 41 having a thickness larger than 200 μm may reduce the resolution and the modulation transfer function (MTF) of a captured image, which is caused by that light generated in the scintillator layer 3 or light reflected by a reflective layer 42 is reflected at the interface of the resin layer 41 with an adjacent member to increase scattering of the light. The material of the resin layer 41 may be a common organic sealing material such as a silicone resin, an acrylic resin, or an epoxy resin; an organic film of polyparaxylene formed by CVD; or a hot-melt resin. In particular, the resin layer 41 can be made of a resin that hardly transmits moisture.

Here, the hot-melt resin will be described. The hot-melt resin is a resin that melts when its temperature is increased and solidifies when its temperature is decreased. The heated molten hot-melt resin is adhesive to other organic materials and inorganic materials, but the hot melt in the solid state at ordinary temperature is not adhesive. Since the hot-melt resin does not contain polar solvents, other solvents, and water, even if the scintillator layer 3 (for example, a scintillator layer having a columnar crystal structure made of an alkali halide) is in contact with the hot-melt resin, the hot-melt resin does not dissolve the scintillator layer 3. Therefore, the hot-melt resin can be particularly used as the resin layer 41 of the scintillator protecting layer 4. The hot-melt resin is different from a solvent volatilization curing-type adhesive resin, which is produced by solvent coating by dissolving a thermoplastic resin in a solvent. Furthermore, the hot-melt resin is different from a chemical reaction-type adhesive resin, which is produced by chemical reaction of, typically, epoxy. The materials for the hot-melt resin are classified according to types of the base polymers (base materials) being main components, and, for example, a polyolefin, polyester, or polyamide resin can be used. The resin layer 41 of the scintillator protecting layer 4 is required to be excellent in moisture-resistance and in light transmittance for the visible light generated by the scintillator layer 3. Examples of the hot-melt resin that satisfies the moisture-resistance necessary as the resin layer 41 of the scintillator protecting layer 4 include polyolefin resins and polyester resins. In particular, the polyolefin resins are low in moisture absorption and also high in light transmittance. Accordingly, a polyolefin-based hot-melt resin can be used as the resin layer 41 of the scintillator protecting layer 4. The main component of the polyolefin resin can be at least one selected from ethylene-vinyl acetate copolymers, ethylene-acrylic acid copolymers, ethylene-acrylic acid ester copolymers, ethylene-methacrylic acid copolymers, ethylene-methacrylic acid ester copolymers, and ionomer resins. An example of the hot-melt resin having an ethylene-vinyl acetate copolymer as a main component is Hirodyne 7544 (a product of Hirodyne Co., Ltd.). An example of the hot-melt resin having an ethylene-acrylic acid ester copolymer as a main component is O-4121 (a product of Kurabo Industries Ltd.). An example of the hot-melt resin having an ethylene-methacrylic acid ester copolymer as a main component is W-4110 (a product of Kurabo Industries Ltd.). An example of the hot-melt resin having an ethylene-acrylic acid ester copolymer as a main component is H-2500 (a product of Kurabo Industries Ltd.). An example of the hot-melt resin having an ethylene-acrylic acid copolymer as a main component is P-2200 (a product of Kurabo Industries Ltd.). An example of the hot-melt resin having an ethylene-acrylic acid ester copolymer as a main component is Z-2 (a product of Kurabo Industries Ltd.). The scintillator layer 3 is covered with the resin layer 41 and also a resin being a sealing member. The resin covering the scintillator layer 3 extends from the upper side of the scintillator layer 3 toward the sensor panel side and among the plurality of the columnar crystals on the effective pixel region and among the plurality of columnar crystals on the peripheral region. Therefore, the thickness of the overlap of the scintillator layer 3 and the resin in the thickness direction on the peripheral region is larger than that on the effective pixel region. Since the radiographic imaging apparatus has such a structure, the scintillator layer 3 can be protected from the moisture from the outside.

The reflective layer 42 has a function of improving light use efficiency by reflecting light that is converted from radiation and emitted by the scintillator layer 3 and proceeds to the oppose side of the photoelectric conversion element 16 and by guiding the light to the photoelectric conversion element 16. The reflective layer 42 inhibits light beams other than the light generated in the scintillator layer 3 from entering the photoelectric conversion element 16. The reflective layer 42 may be metal foil or a metal thin film and can have a thickness of 1 to 100 μm. The reflective layer 42 having a thickness smaller than 1 μm may be reduced in light shielding property or may be reduced in moisture resistance due to occurrence pinhole during the production of the reflective layer 42. Conversely, the reflective layer 42 having a thickness of larger than 100 μm absorbs a large amount of radiation to decrease the amount of light emitted by the scintillator layer 3, which may cause a reduction in image quality. If the amount of radiation is increased for preventing a reduction in image quality, the exposure dose to a subject to be imaged may be increased. Furthermore, it may be difficult to cover the reflective layer 42 along its surface shape, and thereby the reflection performance and the moisture-resistance performance may be decreased. The reflective layer 42 can be made of a metal material such as silver, a silver alloy, aluminum, an aluminum alloy, gold, or copper. Usually, aluminum can be used because of its excellent reflectance and inexpensive price.

The resin layer 43 is provided as a protective layer for the reflective layer 42. The resin layer 43 may be made of a polyethylene terephthalate resin.

### First Embodiment

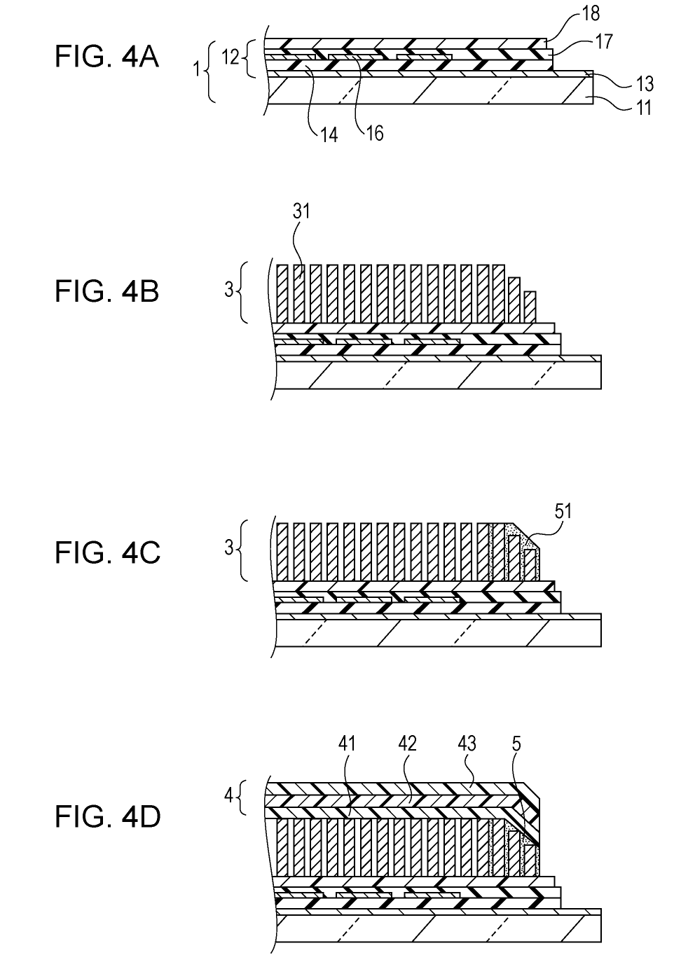

FIGS. 4A to 4D are partial cross-sectional views illustrating a method of producing a radiographic imaging apparatus of a first embodiment.

FIG. 4A shows the step of preparing a sensor panel 1. The sensor panel 1 has a substrate 11 of glass, wiring 13 disposed on the substrate 11, a first insulating layer 14 made of SiNx, PIN-type photoelectric conversion elements 16 included in pixels, a second insulating layer 17 made of SiNx, and a protective layer 18 made of a polyimide resin. The pixels each include the photoelectric conversion element 16 and a TFT (not shown) being a switching element connected to the photoelectric conversion element 16. The TFT is connected to the wiring 13.

FIG. 4B shows the step of forming a scintillator layer 3 having a plurality of columnar crystals on the sensor panel 1. The scintillator layer 3 is formed on the sensor panel 1 using a vapor deposition apparatus. The periphery of the sensor panel 1 where the scintillator layer 3 will not be formed is covered with a mask (not shown), and then the material, CsI:Tl, for forming the scintillator layer 3 is deposited. The thickness of the scintillator layer 3 is about 500 μm in the effective pixel region A, and the minimum thickness in the sealing region B is 80% or less of the average thickness of the effective pixel region A. The scintillator layer 3 has a columnar crystal structure, and the columnar crystals are arranged so as to at least partially have gaps between adjacent columnar crystals. By doing so, the radiographic imaging apparatus can form an image having satisfactory resolution.

FIG. 4C shows the step of forming the sealing member 5. In this step, a resin 51 of the sealing member 5 is applied and cured. Specifically, first, an epoxy resin is applied onto the periphery of the scintillator layer 3 by a seal dispenser to allow the resin to penetrate the gaps among a plurality of the columnar crystals. Then, the epoxy resin is cured at 120° C. for 60 min under a nitrogen atmosphere. The resin 51 of the sealing member 5 must be applied not to infiltrate into the effective pixel region A, in order to prevent a decrease in resolution of an image formed by the radiographic imaging apparatus by the infiltration of the resin 51 into the effective pixel region A. Furthermore, the resin 51 of the sealing member 5 can be applied to the area in the periphery of the scintillator layer 3 where the thickness of the scintillator layer 3 is 80% or less of the average thickness in the effective pixel region A. By doing so, the peripheral region C can be reduced in size. In the sealing member 5 shown in FIG. 3A or 3B, a material mixture where a light-absorbing member or a light-reflecting member is dispersed in a resin in advance is applied onto the periphery of the scintillator layer 3. For example, a light-absorbing member such as carbon black having an average particle diameter of 500 nm is uniformly dispersed in an epoxy resin, or a light-reflecting member such as titanium oxide particles having an average particle diameter of 500 nm is uniformly dispersed in an epoxy resin.

FIG. 4D shows the step of forming a scintillator protecting layer 4 on the scintillator layer 3. The scintillator protecting layer 4 is formed by laminating an alumina sheet being the reflective layer 42 and a polyethylene terephthalate (PET) sheet being the resin layer 43 and then transfer-bonding a polyolefin hot-melt resin being the resin layer 41 to the reflective layer 42 using a heat roller. This three-layer scintillator protecting layer 4 is disposed on the scintillator layer 3, and the entire scintillator protecting layer 4 is heated to be fixed to the scintillator layer 3 by welding of the resin layer 41. In order to further improve the adhesion, the portion of the periphery of the scintillator protecting layer 4 facing the sealing member 5 may be pressure-bonded with a bar-type heat-pressure bonding head. The heat pressure treatment can be performed at a pressure of 1 to 10 kg/cm² and a temperature that is higher than the incipient melting temperature of the hot-melt resin by 10° C. to 50° C. for 1 to 60 sec.

Then, periphery circuits are connected to wiring 13 with ACF (not shown).

The thus-produced radiographic imaging apparatus has a structure where the region of the scintillator layer 3 corresponding to the effective pixel region A is protected by being enclosed within the sensor panel 1, the sealing member 5, and the scintillator protecting layer 4, which prevents moisture and the like from infiltrating into the region of the scintillator layer 3 corresponding to the effective pixel region A. In addition, since the portion of the scintillator layer 3 where the thickness is reduced is used as the sealing, the periphery region is reduced in size, which provides a radiographic imaging apparatus having a sufficient effective pixel region and also having a reduced size.

### Second Embodiment

A second embodiment is different from the first embodiment in that a sequential body is formed in the periphery of the scintillator layer for preventing the sealing member from infiltrating into the effective pixel region. The radiographic imaging apparatus and its production process of the second embodiment are as follows:

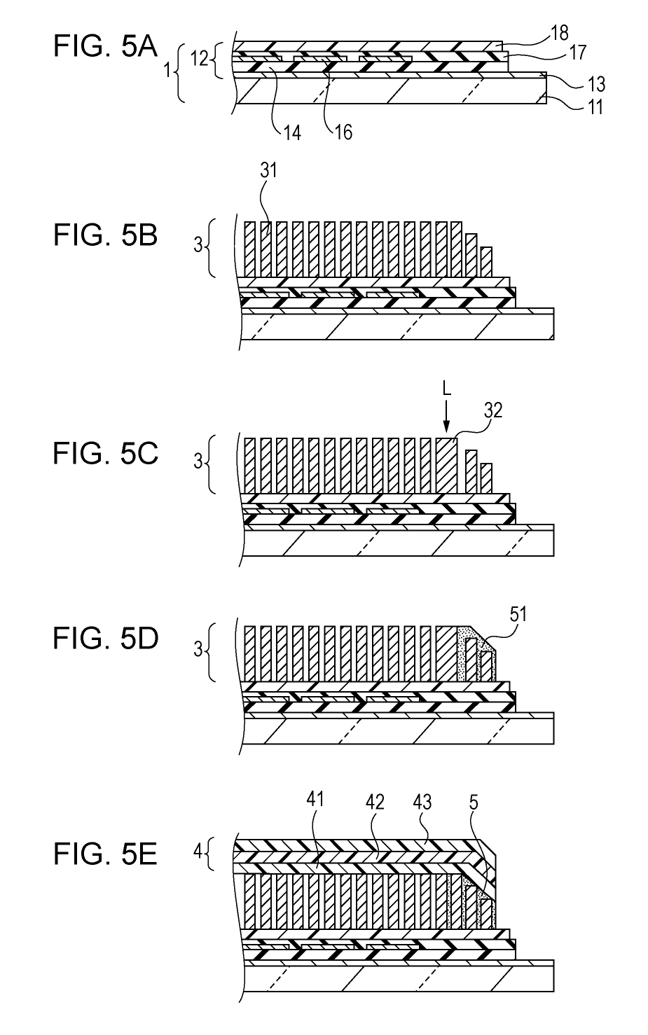

FIG. 5A shows the step of preparing a sensor panel 1. In the sensor panel 1, an active matrix array 12 is formed on a substrate 11. The details are the same as FIG. 4A and its description in the first embodiment.

FIG. 5B shows the step of forming a scintillator layer 3 having a plurality of columnar crystals on the sensor panel 1. The scintillator layer 3 is formed on the sensor panel 1 by a vapor deposition apparatus. The details are the same as FIG. 4B and its description in the first embodiment.

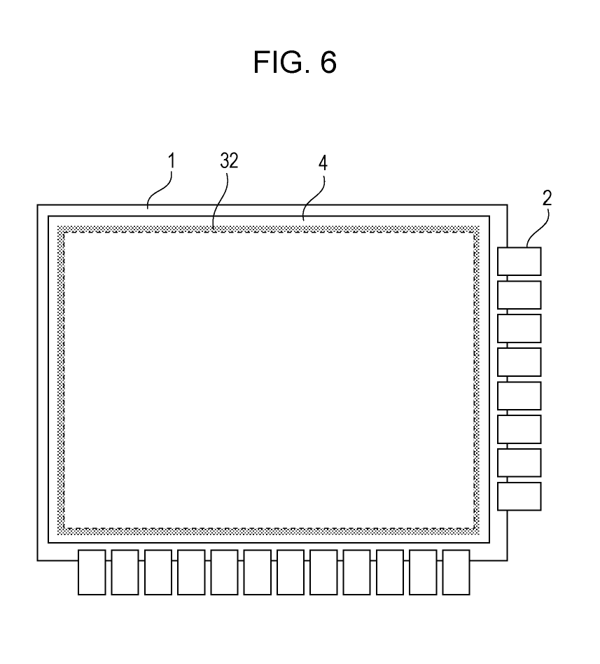

FIG. 5C shows the step of forming a sequential body 32 in the periphery of the scintillator layer 3. The sequential body 32 is formed by heating the scintillator layer 3 to melt the columnar crystals in the outer-area of the effective pixel region A of the scintillator layer 3. For example, the scintillator layer 3 is locally heated and melted by laser irradiation, plasma irradiation, or ion beam irradiation. In FIG. 5C, the sequential body 32 is formed by irradiation of a laser beam L, and a plurality of the columnar crystals that have been heated and melted are unified into a circular crystal after being cooled to form a polycrystal or a single crystal, not having gaps. That is, the sequential body 32 is a sequential high-density crystal region. Such a structure is obtained by deforming crystals so as to reduce the gaps by applying energy of mechanical force such as compression or polishing or of heat. In particular, the sequential high-density crystal region can be formed by applying energy of heat to crystals. The sequential body 32 is formed at the region surrounding the active pixel region A, as shown by reference number 32 in FIG. 6. Since the sequential body 32 of the scintillator layer 3 has impact resistance higher than that of the columnar crystals, in particular, peeling from the end of the scintillator layer 3 is inhibited from reaching the effective pixel region A.

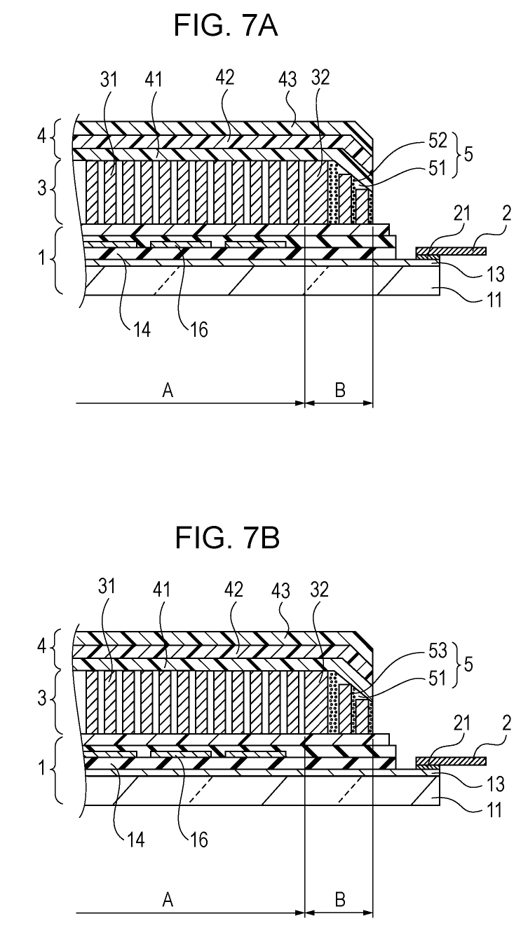

FIG. 5D shows the step of forming a sealing member 5. In this step, a resin 51 of the sealing member 5 is applied and cured. This step is the same as the first embodiment except that the sealing member 5 is applied onto the outside of the sequential body 32. Here, the sequential body 32 functions as a blocking layer for reducing infiltration of the sealing resin 5 into the effective pixel region A. Specifically, the sequential body 32 is a region where the crystals are arranged in a high density, compared to the plurality of the columnar crystals on the peripheral region. In order to function as a blocking layer, the sequential body 32 must be a sequential high-density crystal region, but may be a plurality of high-density crystal regions such as circularly arranged crystals or U-shaped crystals arranged so as to surround the plurality of the columnar crystals on the effective pixel region A. Accordingly, the sequential body 32 can reduce infiltration of the sealing resin 5 into the effective pixel region A, which can inhibit a decrease in image quality. Note that the plurality of the columnar crystals on the peripheral region where the sealing resin 5 is disposed is arranged in the outer region surrounding the sequential high-density crystal region. As shown in FIGS. 7A and 7B, the sealing member 5 may be made of a resin or a material mixture of a resin and a light-absorbing member or a light-reflecting member as in the first embodiment. Accordingly, effect on an image due to outside light entering into the sensor panel 1 can be reduced.

FIG. 5E shows the step of forming a scintillator protecting layer 4 on the scintillator layer 3. The scintillator protecting layer 4 has a three-layer structure and is formed on the scintillator layer 3. The details are the same as FIG. 4D in the first embodiment.

Then, periphery circuits are connected to wiring 13 with ACF (not shown).

The thus-produced radiographic imaging apparatus has a structure where the region of the scintillator layer 3 corresponding to the effective pixel region A is protected by the sensor panel 1, the sealing member 5, and the scintillator protecting layer 4, which prevents moisture and the like from infiltrating into the region of the scintillator layer 3 corresponding to the effective pixel region A. In addition, the sequential body 32 formed in the scintillator layer 3 can prevent infiltration of the applied resin 51 before curing into the effective pixel region of the scintillator layer 3, which can inhibit a reduction in image quality. Furthermore, since the portion of the scintillator layer 3 where the thickness is reduced is used as the sealing, the periphery region is reduced in size, which provides a radiographic imaging apparatus having a sufficient effective pixel region and also having a reduced size.

### Third Embodiment

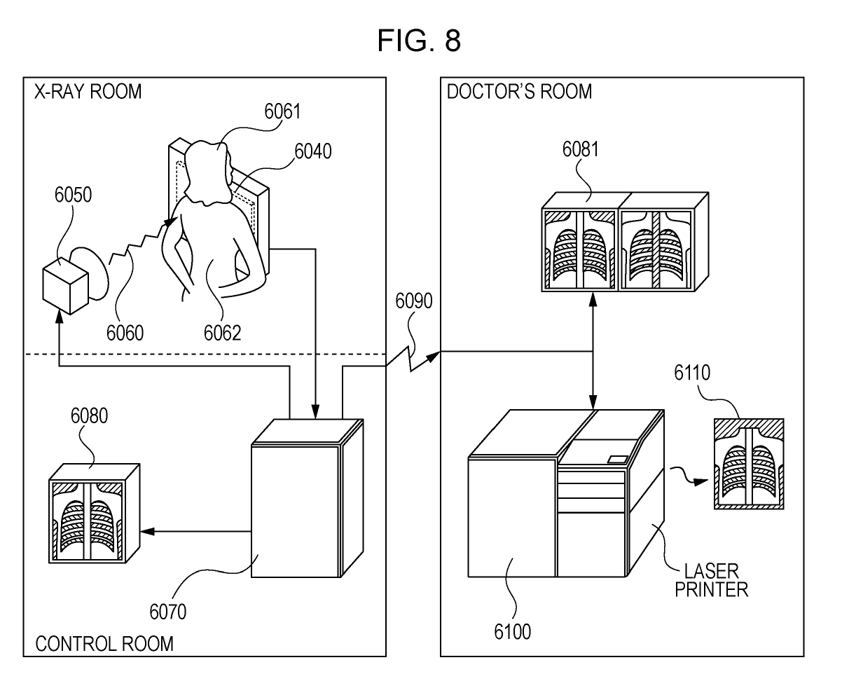

FIG. 8 is a diagram illustrating an example where an X-ray imaging apparatus according to the present invention is applied to an X-ray diagnostic system (radiographic imaging system). X-ray radiation 6060 generated in an X-ray tube 6050 (radiation source) passes through a predetermined region 6062 of a patient or test subject 6061 and then enters a radiographic imaging apparatus 6040 mounted with a sensor panel and a scintillator on the sensor panel. The incident X-ray radiation contains information on internal body of the patient 6061. In response to the incidence of the X-ray radiation, the scintillator emits light, and this light is photoelectrically converted to give electric signal information. This information is converted into digital signals, and the signals are image-processed to generate images by an image processor 6070 being a signal processing unit; the resultant images can be observed in a display 6080 being a display unit of a control room. The radiographic imaging system includes at least a radiographic imaging apparatus and a signal processing unit where signals from the radiographic imaging apparatus are processed.

The digital signals can also be transferred from the image processor 6070 to a remote location by a transfer processing unit such as a network 6090 and can be displayed on a display 6081 being a display unit or stored in a recording unit such as an optical disk in a doctor room and the like of a separate location, thereby allowing a doctor of the remote location to make a diagnosis. Furthermore, the information can be recorded in a film 6110 being a recording medium by a film processor 6100 being a recording unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-288460 filed Dec. 18, 2009, which is hereby incorporated by reference herein in its entirety.

What is claimed is:

1. A radiographic imaging apparatus comprising:
a sensor panel having an effective pixel region and a peripheral region surrounding the effective pixel region;
a scintillator layer disposed on the effective pixel region and the peripheral region of the sensor panel; and
a scintillator protecting layer disposed on the scintillator layer, wherein
the scintillator layer comprises a plurality of columnar crystals disposed on the effective pixel region, a plurality of columnar crystals disposed on the peripheral region, and a resin disposed between the plurality of the columnar crystals on the peripheral region and surrounding the plurality of the columnar crystals on the effective pixel region; and
the plurality of the columnar crystals on the effective pixel region is enclosed by the sensor panel, the scintillator layer, and the resin.

2. The radiographic imaging apparatus according to claim 1, wherein
the scintillator layer further comprises a sequential high-density crystal region on the peripheral region, wherein
the plurality of the columnar crystals on the effective pixel region is surrounded by the sequential high-density crystal region; and
the plurality of the columnar crystals on the peripheral region is arranged in the sequential high-density crystal region.

3. The radiographic imaging apparatus according to claim 1, wherein the scintillator protecting layer is disposed on the scintillator layer only.

4. The radiographic imaging apparatus according to claim 1, wherein the resin contains a light-absorbing member therein.

5. The radiographic imaging apparatus according to claim 4, wherein the light-absorbing member includes particles made of a material selected from carbon black, ivory black, mars black, peach black, lamp black, and aniline black.

6. The radiographic imaging apparatus according to claim 1, wherein the resin contains a light-reflecting member therein.

7. The radiographic imaging apparatus according to claim 6, wherein the light-reflecting member includes particles made of titanium oxide or zinc oxide.

8. The radiographic imaging apparatus according to claim 1, wherein the resin is at least one of epoxy, acrylic, silicone, polyester, polyolefin, and polyamide resins.

9. The radiographic imaging apparatus according to claim 1, wherein the scintillator protecting layer contains a metal selected from silver, silver alloys, aluminum, aluminum alloys, gold, and copper.

10. The radiographic imaging apparatus according to claim 1, wherein the effective pixel region is a region where a plurality of pixels each having a photoelectric conversion element are arranged.

11. The radiographic imaging apparatus according to claim 1, wherein the peripheral region of the scintillator layer has a thickness equal to a thickness of the effective pixel region of the scintillator.

12. The radiographic imaging apparatus according to claim 1, wherein the peripheral region of the scintillator layer has a thickness smaller than a thickness of the effective pixel region of the scintillator.

13. A radiographic imaging system comprising:
a radiographic imaging apparatus according to claim 1; and
a signal processing unit where signals from the radiographic imaging apparatus are processed.

14. A radiographic imaging apparatus comprising:
a sensor panel having an effective pixel region and a peripheral region surrounding the effective pixel region;
a scintillator layer disposed on the effective pixel region and the peripheral region of the sensor panel; and
a resin covering the scintillator layer, wherein:
the scintillator layer comprises a plurality of columnar crystals on the effective pixel region and a plurality of columnar crystals on the peripheral region; and
the resin covering the scintillator layer extends from the upper side of the scintillator layer toward the sensor panel side between the plurality of the columnar crystals on the effective pixel region and among the plurality of the columnar crystals on the peripheral region, and the thickness of an overlap of the scintillator layer and the resin in the thickness direction on the peripheral region is larger than that of the overlap of the scintillator layer and the resin on the effective pixel region.

15. A radiographic imaging system comprising:
a raphic imaging apparatus according to claim 14; and
a signal processing unit where signals from the radiographic imaging apparatus are processed.

16. A method of producing a radiographic imaging apparatus comprising:
preparing a sensor panel having an effective pixel region where a plurality of pixels having photoelectric conversion elements are arranged and a peripheral region surrounding the effective pixel region;
forming a scintillator layer having a plurality of columnar crystals on the effective pixel region and on the peripheral region of the sensor panel;
applying a resin among the columnar crystals on the peripheral region of the sensor panel; and
forming a scintillator protecting layer covering the effective pixel region and the peripheral region.

17. The method according to claim 16 further comprising:
before applying the resin, heating the plurality of the columnar crystals on the peripheral region to form a sequential high-density crystal region on the peripheral region so that the plurality of the columnar crystals on the effective pixel region is surrounded by the sequential high-density crystal region and that the plurality of the columnar crystals on the peripheral region is arranged in the circumference of the sequential high-density crystal region.

18. The method according to claim 16, wherein the resin is a material mixture containing a light-absorbing member or a light-reflecting member.
